(19) United States
(12) Patent Application Publication
(10) Pub. No.: US 2024/0222282 A1
(43) Pub. Date: Jul. 4, 2024

(54) ZERO MISALIGNED PAD AND VIA METALLIZATION STRUCTURES IN GLASS PACKAGE SUBSTRATES

(71) Applicant: Intel Corporation, Santa Clara, CA (US)

(72) Inventors: Sameer Paital, Mesa, AZ (US); Gang Duan, Chandler, AZ (US); Srinivas Pietambaram, Chandler, AZ (US); Kristof Darmawikarta, Chandler, AZ (US)

(73) Assignee: Intel Corporation, Santa Clara, CA (US)

(21) Appl. No.: 18/091,150

(22) Filed: Dec. 29, 2022

(51) Int. Cl. H01L 23/538; H01L 21/48; H01L 23/00; H01L 23/15; H01L 23/498

(52) U.S. Cl. CPC H01L 23/5386; H01L 21/486; H01L 23/15; H01L 23/49816; H01L 23/49866; H01L 23/5384; H01L 24/16; H01L 24/81; H01L 25/0655

(57) ABSTRACT

Apparatuses, systems, assemblies, and techniques related to forming a metallization structure in a glass core package substrate such that the metallization structure has multiple portions with differing cross-sectional widths with little or no misalignment between the portions are described. Such techniques including mounting the glass core substrate to a stage, applying multiple laser exposures to a location of the glass core substrate to define laser treated regions of the glass core substrate corresponding to the portions of the metallization structure, removing the laser treated regions, and filling the openings with metal to form the embedded zero misaligned metallization structure.

### BACKGROUND

Higher performance, lower cost, increased miniaturization, and greater packaging density of integrated circuits (ICs) within integrated circuit devices are ongoing goals of the electronics industry. Traditional IC package substrates use organic epoxy-based cores as starting substrates. These cores provide mechanical support for the rest of the buildup layers on the front and back sides of the package. With the increasing demand for multichip packaging, tighter bump pitches, line space scaling for higher density interconnects, larger form factors, and thinner total package thickness, such organic cores become a limiter to advancing the IC package. Glass core package substrates are a promising replacement for organic core substrates. Glass core package substrates are expected to provide mechanical benefit including reduced warpage, smaller thickness variation, and others as well as design flexibility such as tighter through hole pitches, finer core metallization routing, and others.

However, deployment of glass core package substrates faces challenges including those associated with tighter line spacing and bump pitches. Notably, laser and lithography patterning accuracy in typical semi additive process (SAP) flows may limit the implementation of glass core package substrates. It is with respect to these and other considerations that the present improvements have been needed. Such improvements may become critical as the desire to use glass core package substrates in advanced device becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating methods for forming metallization structure having minimally misaligned portion within a glass core substrate;

FIG. 2 illustrates a cross-sectional view of a glass core substrate workpiece including a glass core substrate for the formation of a metallization structure having minimally misaligned portions;

FIG. 3 illustrates a cross-sectional view of a glass core substrate to stage mounting of a glass core substrate to a stage of a laser exposure apparatus;

FIG. 4 illustrates a top-down view of a glass core substrate having multiple laser treatment lateral locations;

FIG. 5 illustrates a cross-sectional view of a glass core substrate workpiece similar to the glass core substrate workpiece of FIG. 2 during and after the formation of through via laser treated regions;

FIG. 6 illustrates a cross-sectional view of a glass core substrate workpiece similar to the glass core substrate workpiece of FIG. 2 during and after the formation of tapered via laser treated regions;

FIG. 7 illustrates a cross-sectional view of a glass core substrate workpiece similar to the glass core substrate workpiece of FIG. 5 during and after the formation of pad laser treated regions;

FIG. 8 illustrates a cross-sectional view of a glass core substrate workpiece similar to the glass core substrate workpiece of FIG. 7 after the removal of laser treated regions to provide openings in the glass core substrate;

FIG. 9 illustrates a cross-sectional view of a glass core substrate workpiece similar to the glass core substrate workpiece of FIG. 8 after formation of metallization structures within openings of the glass core substrate;

FIG. 10 illustrates a cross-sectional view of a glass core substrate workpiece similar to the glass core substrate workpiece of FIG. 9 after removal of overburden metal to provide completed embedded metallization structures in the glass core substrate;

FIG. 11 illustrates cross-sectional views of a pad portion and a via portion taken at interface of a metallization structure;

FIG. 12 illustrates a cross-sectional view of a glass core substrate workpiece similar to the glass core substrate workpiece of FIG. 6 after pad patterning, laser treated glass removal, metallization, and overburden metal removal to form metallization structures having tapered via portions;

FIG. 13 illustrates a cross-sectional view of a glass core substrate workpiece similar to the glass core substrate workpiece of FIG. 10 with a slight misalignment between a via portion and a pad portion;

FIG. 14 illustrates an example microelectronic device assembly including a glass core substrate having a metallization structure with different lateral widths;

FIG. 15 illustrates exemplary systems deploying a glass core substrate having a metallization structure with different lateral widths; and

FIG. 16 is a functional block diagram of an electronic computing device, all arranged in accordance with some embodiments of the present disclosure.

### DETAILED DESCRIPTION

One or more embodiments or implementations are now described with reference to the enclosed figures. While specific configurations and arrangements are discussed, this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. Herein, the term “predominantly” indicates not less than 50% of a particular material or component while the term “substantially pure” indicates not less than 99% of the particular material or component. Unless otherwise indicated, such material percentages are based on atomic percentage. As used herein, the terms “monolithic”, “monolithically integrated”, and similar terms indicate the components of the monolithic overall structure form a indivisible whole not reasonably capable of being separated.

The term “package” generally refers to a self-contained carrier of one or more dice, where the dice are attached to the package substrate, and may be encapsulated for protection, with integrated or wire-boned interconnects between the dice and leads, pins or bumps located on the external portions of the package substrate. The package may contain a single die, or multiple dice, providing a specific function. The package is usually mounted on a printed circuit board for interconnection with other packaged integrated circuits and discrete components, forming a larger circuit. Here, the term “dielectric” and the term “insulative and any similar term generally refers to any number of non-electrically conductive materials that make up the structure of a package substrate. For purposes of this disclosure, dielectric material may be incorporated into an integrated circuit package as layers of laminate film or as a resin molded over integrated circuit dice mounted on the substrate. Here, the term “metallization” generally refers to metal layers formed over and/or through a package substrate. The metal layers are generally patterned to form metal structures such as traces and bond pads. The metallization of a package substrate may be confined to a single layer or in multiple layers separated by layers of dielectric. Here, the term “assembly” generally refers to a grouping of parts into a single functional unit. The parts may be separate and are mechanically assembled into a functional unit, where the parts may be removable. In another instance, the parts may be permanently bonded together. In some instances, the parts are integrated together. Throughout the specification, and in the claims, the term “connected” means a direct connection, such as electrical, mechanical, or magnetic connection between the things that are connected, without any intermediary devices. The term “coupled” means a direct or indirect connection, such as a direct electrical, mechanical, magnetic or fluidic connection between the things that are connected or an indirect connection, through one or more passive or active intermediary devices.

Apparatuses, systems, architectures, and techniques are described herein related to forming metallization structures in a glass core substrate such that the metallization structures include a via and a pad that little or no misalignment there between.

As discussed, it is desirable to deploy glass core substrates in some packaging contexts. For example, glass core substrates offer a variety of potential advantages such as tighter bump pitches, line space scaling for higher density interconnects, larger form factors, thinner total package thickness, and others, particularly in the context of advanced packaging solutions such as multichip packages. In some embodiments, minimal or zero misaligned pad to via metallization structures are formed using laser induced deep etching (LIDE) techniques. In some embodiments, a glass core substrate is mounted to a stage such as a laser stage or table. At a first location of the glass core substrate, a first laser treatment is applied to establish a sensitized portion of the glass core substrate that corresponds to either a pad portion or a via portion of an eventual metallization structure. Without intervening removal of the glass core substrate from the stage, a second laser treatment is applied at the location. The second laser treatment sensitizes the portion of the glass core that corresponds to the other of the pad portion or via portion of the desired metallization structure. It is noted the wafer stage may or may not move to another location between such first and second laser treatments. However, in either case, the glass core substrate to stage mounting is not broken between the two laser treatments. As used herein, the term glass core substrate to stage mounting indicates a securement of the glass core substrate to the stage. Such mounting is not broken by movement of the stage but only upon release of the glass core substrate from the stage such as by vacuum release and physical removal of the glass core substrate from the stage.

After the first and second laser treatments sensitize the glass core substrate such that there is no or little misalignment therebetween, the sensitized portions are removed by etch processing. Herein, alignment between the pad and via portions are generally illustrated with respect to vertical centerlines of the pad and the via being aligned (i.e., such that the centerlines of the pad and the via are the same line). However, such alignment may be provided in any suitable manner in accordance with the layout design of the pad and via portions of the metallization structure. Subsequent to etching the glass core substrate to reveal the opening defining the pad and via portions, metallization processing is used to fill the opening with a continuous metallization structure having the desired dimensionality. As used herein, the term continuous metallization structure indicates a structure having a common metal material and microstructure. For example, the pad and via of the metallization structure may be fabricated in the same processing operation(s). In some embodiments, the metallization structure is fabricated by electroplating techniques (e.g., electrolytic deposition, or elytic metallization) after a seed metal sputter operation. Such metal fabrication may provide an overburden that is then removed by planarization techniques, for example.

Such minimal or zero misaligned via and pad structures provide an advancement over current via and pad structure processes such as laser and lithography patterning during application of semi additive process (SAP) techniques. Whereas such techniques have misalignment errors in the 5-10 μm range, the techniques discussed herein have misalignment errors of not more than 100 nm, not more than 50 nm, or not less than 5 nm. Such improved alignment enables deployment of glass core packages with fine line spacing (2/2 μm FLS) and bump pitches (30 μm), or smaller dimensions. In turn, the structures and techniques discussed herein enable a wide range of IC package advancements. For example, multichip packaging architectures for increased functionalities and an increased fine die-to-die interconnections such as hyper chip stacking (Si interposer), embedded multi-die interconnect bridge (EMIB), and 2.5D/3D heterogeneous integration architectures may be enabled. Other advantages will be evident in view of the following disclosure.

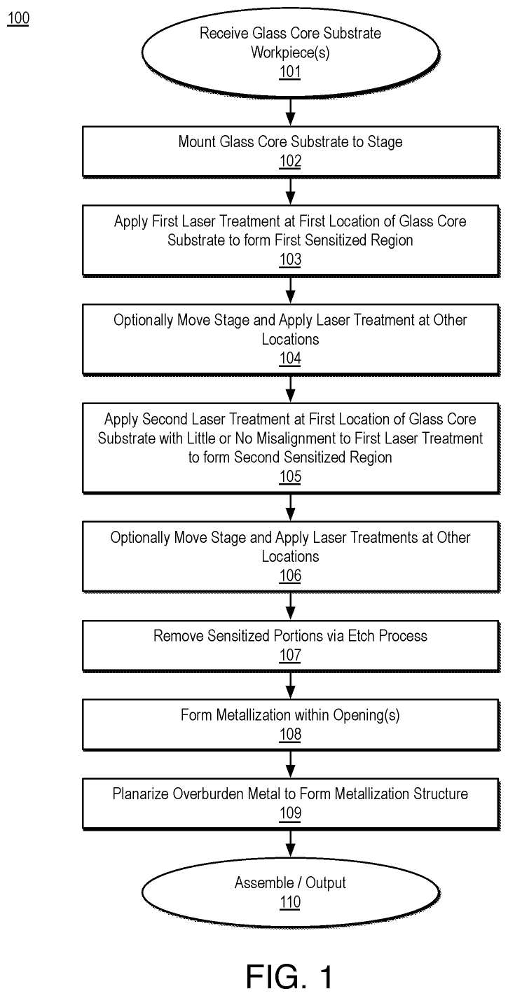

FIG. 1 is a flow diagram illustrating methods 100 for forming metallization structure having minimally misaligned portion within a glass core substrate, arranged in accordance with some embodiments of the disclosure. Methods 100 may be practiced, for example, to fabricate any apparatus or system having a continuous metallization structure with a first portion (e.g., via) and a second portion (e.g., pad) of differing cross-sectional widths with zero or minimal misalignment therebetween.

Methods 100 begin at input operation 101, where a workpiece is received for processing. In some embodiments, a glass core substrate is received. The glass core substrate may be any suitable glass material such as sodium borosilicate glass. Furthermore, the glass core substrate may have any suitable format for use as a package substrate, interposer, or the like such that one or more integrated circuit (IC) dies or chips are to be coupled to at least one surface thereof. Prior to input operation 101, the glass core substrate may be preprocessed in any suitable manner. For example, the glass core substrate may include metallization layers on or within the glass core substrate, devices on or within the glass core substrate, build up layers on one or more surfaces of the glass core substrate, or the like.

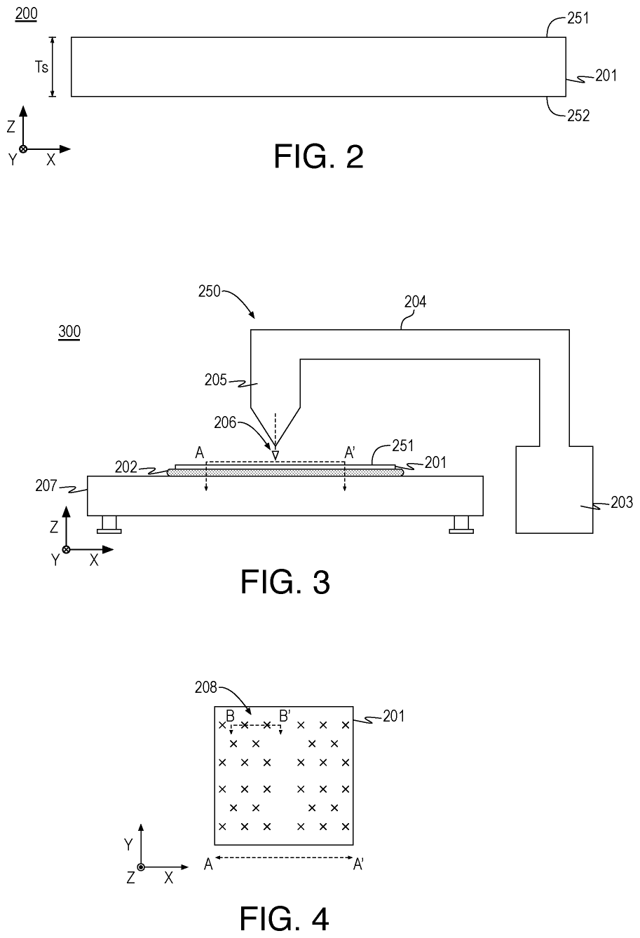

FIG. 2 illustrates a cross-sectional view of a glass core substrate workpiece 200 including a glass core substrate 201 for the formation of a metallization structure having minimally misaligned portions, in accordance with some embodiments. As shown, glass core substrate 201, having a top surface 251 and an opposing bottom surface 252 is received for processing. Glass core substrate 201 may include any suitable glass material such as sodium borosilicate glass. Glass core substrate 201 may also include one or more buildup layers (not shown) on either side thereof. For example, top surface 251 and/or bottom surface 252 of glass core substrate 201 may be glass or a buildup layer on a central glass core. Glass core substrate 201 may include one or more layers of metallization, one or more integrated or discrete devices, or the like. In some embodiments, glass core substrate 201 may include one or more devices or integrated circuits embedded therein. Glass core substrate 201 may have any suitable thickness, Ts, such as a thickness in the range of 50 to 500 μm.

Returning to FIG. 1, processing continues at operation 102, where the glass core substrate is mounted to a stage of a laser treatment or laser patterning device. The glass core substrate may be mounted to the stage using any suitable technique or techniques. For example, the glass core substrate may be picked from a rack or container by a robot arm that places the glass core substrate on the stage. In some embodiments, the glass core substrate is secured to the stage by a vacuum (e.g., via vacuum stage or chuck) or a mechanical means such as a clamp. As discussed herein, once the glass core substrate is mounted to the stage, a glass core substrate to stage mounting is established. Although the glass core substrate and stage may move relative to one another by a de minimis amount after such mounting, the glass core substrate to stage mounting is not broken or lost until the glass core substrate is actively removed from the stage. For example, the vacuum or clamp may be removed and the glass core substrate may be picked from the stage after processing. Such release and removal breaks the glass core substrate to stage mounting. Notably, the glass core substrate to stage mounting remains until all laser processing on the glass core substrate is completed.

FIG. 3 illustrates a cross-sectional view of a glass core substrate to stage mounting 300 of glass core substrate 201 to a stage 202 of a laser exposure apparatus 250, in accordance with some embodiments. As shown, laser exposure apparatus 250 may include a laser generator 203 (laser source), an optical route 204, and an optics column 205 to deliver a laser beam 206 to top surface 251 of glass core substrate 201. In some embodiments, laser exposure apparatus 250 is an excimer laser that delivers laser beam 206 at a wavelength of 193 nm, at a short pulse width in the nano seconds regime. Stage 202 moves relative to frame 207 of laser exposure apparatus 250 and relative to optics column 205 to place different lateral locations of glass core substrate 201 under laser beam 206. As discussed, glass core substrate 201 is mounted to stage 202 to provide glass core substrate to stage mounting 300, which is not broken until all laser treatments to glass core substrate 201 are completed.

Returning to FIG. 1, processing continues at operation 103, where a first laser treatment is applied to the glass core substrate to sensitize a first portion of the glass core substrate at a first lateral location of the glass core substrate. As used herein, the term sensitized indicates a portion of a glass core substrate that has been laser treated and may then be removed by etch techniques in accordance with LIDE processing, for example. Such sensitization may also be characterized as modification or the like. The laser treatment may be performed using any suitable technique or techniques. In some embodiments, an excimer laser at wavelength of 193 nm and shorter pulse width in the nano seconds regime is applied. An excimer laser, for example, may drill high quality through glass vias and pads in all types of silicate based glass with thicknesses in the range of 50 to 500 μm. Although other thicknesses may be used, it is noted that thicknesses greater than 500 μm can cause difficulties during such laser treatment processing such as cracking of the glass, heat damage, or others.

Notably, the laser treatment performed at operation 103 is different than a subsequent laser treatment performed at the same lateral location, as discussed with respect to operation 105 herein below. The laser treatments may differ in any suitable attributes to effect differing glass sensitization or laser treated regions having different cross-sectional widths or dimensions and different depths. For example, the first laser treatment may sensitize the glass core substrate to form a sensitized via region having a higher aspect ratio (i.e., height to width ratio) that optionally extends through the glass core substrate, and the second laser treatment may sensitize the glass core substrate to form a sensitized via region having a lower aspect ratio and greater width, or vice versa. Notably, the via sensitization and the pad sensitization may be performed in either order.

Furthermore, the first and second laser treatments may differ in any suitable manner inclusive of duration, intensity, scan rate (i.e., a rate at which the laser moves in a lateral dimension), focal plane size (i.e., the size of the laser pattern on the surface of the glass core substrate), or a combination thereof. In some embodiments, the first laser treatment is at a first laser intensity and duration and the second laser treatment is at a second laser intensity and duration less than the first laser intensity and duration. As used herein the term intensity and duration indicates a product of the laser intensity and laser duration per unit area of the surface of the glass core substrate. Notably, laser treatment of a first lateral location may include scanning near a target lateral location without gross movement to a second lateral location.

As shown with respect to optional operation 104, the glass core substrate may optionally be moved between the laser treatments at the first lateral location to apply laser treatments at other lateral locations. For example, the glass core substrate may be moved relative to the laser and laser treatments are applied at another location or locations. Such techniques may improve throughput by reducing risks related to laser residence time problems, over-treating a particular location, and the like. In some embodiments, one or more of the laser treatments at other locations are the same as that applied at operation 103, although they need not be. The number of other locations/laser treatments may be any suitable number. In some embodiments, first laser treatments are applied at all locations of the glass core substrate during a first pass or first laser treatments are applied within a glass core substrate region that is to be later singulated from a glass core substrate panel, or the like.

FIG. 4 illustrates a top-down view of glass core substrate 201 having multiple laser treatment lateral locations 208, in accordance with some embodiments. For example, the top-down view of FIG. 4 is the view taken at A-A′ in FIG. 3. As shown, during the discussed glass core substrate to stage mounting, multiple lateral locations 208 are to be laser treated. As used herein, the term lateral location indicates a location of glass core substrate 201 in the x-y plane (i.e., laterally across top surface 251 of glass core substrate 201). Such multiple lateral locations 208 may receive the same laser treatments, or they may be different.

With reference to FIG. 3, stage 202 moves glass core substrate 201 to position one of lateral locations 208 under laser beam 206, the pertinent laser treatment is applied, and stage 202 then moves glass core substrate 201 to position another of lateral locations 208 under laser beam 206, the pertinent laser treatment is applied, and so on. In some embodiments, two laser treatments (i.e., those discussed with respect to operations 103, 105) are performed without movement between lateral locations 208. That is, both laser treatments may be performed at a lateral location to complete the treatment at that lateral location. In other embodiments, a first laser treatment (i.e., the laser treatment discussed with respect to operation 103) is performed at a first lateral location, stage 202 moves glass core substrate 201 to another lateral location for treatment at that location, and then stage 202 moves glass core substrate 201 returns to the first lateral location for application of the second laser treatment (i.e., the laser treatment discussed with respect to operation 105). Such embodiments may improve throughput and quality relative to performing both at the first lateral location without movement because the latter case may cause laser residence time problems.

In either case, both laser treatments (i.e., those discussed with respect to operations 103, 105) or additional multiple laser treatments (if applied) are performed at the first lateral location without breaking the initial glass core substrate to stage mounting. That is, glass core substrate 201 is not removed from stage 202 (or laser table) between laser treatment. Such laser treatments may also be characterized as exposures. Relative to breaking the initial glass core substrate to stage mounting and remounting glass core substrate 201 between exposures, misalignment problems are drastically reduced or even eliminated by not breaking the initial glass core substrate to stage mounting.

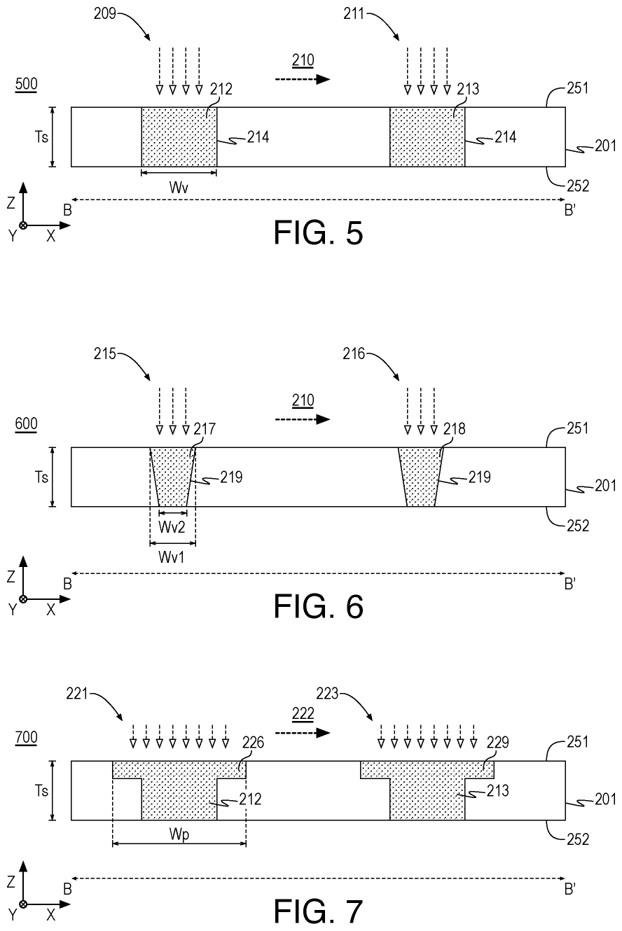

FIG. 5 illustrates a cross-sectional view of a glass core substrate workpiece 500 similar to glass core substrate workpiece 200 during and after the formation of through via laser treated regions 212, 213, in accordance with some embodiments. For example, the cross-sectional view of FIG. 5 is the view taken at B-B′ in FIG. 4. As shown, a first laser treatment (or exposure) 209 is applied to glass core substrate 201 to form laser treated region 212. First laser treatment 209 may include any characteristics such as a duration, intensity, scan rate, focal plane size, and so on to form laser treated region 212 to define an eventual via portion of a metallization structure. Although discussed herein with respect to via and pad portions for the sake of clarity of presentation, the eventual metallization structure may have any features, structures, or portions having the features, such as differing widths, discussed herein.

As shown, subsequent to laser treatment 209, the discussed stage may move to shift the relative position of glass core substrate with respect to the laser, as shown with respect to lateral shift 210. After lateral shift 210, a first laser treatment 211 is applied to glass core substrate 201 to form laser treated region 213 at different lateral position relative to laser treated region 212. For example, laser treated regions 212, 213 may be offset with respect to by about 200 to 500 μm or more. First laser treatment 211 may include the same characteristics as laser treatment 209 (as shown) or they may be different.

Laser treated regions 212, 213 (or modified regions) may have any characteristics relative to the bulk portions of glass core substrate 201 that make laser treated regions 212, 213 susceptible to subsequent etch processing. As shown, in some embodiments, one or both of laser treated regions 212, 213 have a lateral width, Wv. For example, lateral width Wv may be a diameter of laser treated regions 212, 213. Although illustrated herein with respect to via and pad portions having substantially circular cross-sectional shapes (i.e., such that each the via and the pad is substantially cylindrical), any suitable shapes, volumes, and geometries may be deployed. Lateral width Wv may be any suitable dimension such as a width in the range of 50 to 100 μm or more, such as a lateral width Wv of about 200 μm. In some embodiments, lateral width Wv may be limited to an aspect ratio of laser treated regions 212, 213 of about 1:1. For example, for a thickness Ts of glass core substrate 201 of about 50 μm, the lowest lateral width Wv of laser treated regions 212, 213 may be about 50 μm. As shown, in some embodiments, laser treated regions 212, 213 extend through both top surface 251 and bottom surface 252 to establish eventual through glass vias (TGVs). As shown, in some embodiments, laser treated regions 212, 213 have substantially vertical sidewalls 214.

FIG. 6 illustrates a cross-sectional view of a glass core substrate workpiece 600 similar to glass core substrate workpiece 200 during and after the formation of tapered via laser treated regions 217, 218, in accordance with some embodiments. As shown, a first laser treatment 215 is applied to glass core substrate 201 to form laser treated region 217, as discussed with respect to first laser treatment 209. In some embodiments, laser treated region 217 has a tapered sidewall 219 due to the thickness Ts of glass core substrate 201 and relative lateral width of laser treated region 217. For example, to provide a TGV through a thickness Ts of glass core substrate 201 greater than about 100 μm or greater than about 200 μm, such tapering may occur.

Subsequent to laser treatment 215, lateral shift 210 is optionally applied, and after optional lateral shift 210, a first laser treatment 216 is applied to glass core substrate 201 to form laser treated region 218 at different lateral position relative to laser treated region 217. Laser treatment 216 may include the same characteristics as laser treatment 215 and tapered sidewall 219 may again be evident. As shown, in some embodiments, one or both of laser treated regions 217, 218 have a first lateral width, Wv1, at top surface 251 and a second lateral width, Wv2, at bottom surface 252. For example, lateral widths Wv1,2 may be diameters of laser treated regions 217, 218. Lateral width Wv1 may have any dimensions discussed with respect to lateral width Wv. Lateral width Wv2 may be a fraction of lateral width Wv1 due to the discussed tapered sidewall 219. In some embodiments, lateral width Wv2 is in the range of 50% to 80% of lateral width Wv1. As shown, in some embodiments, even with tapered sidewall 219, laser treated regions extend through bottom surface 252 to establish eventual TGVs.

Returning to FIG. 1, processing continues at operation 105, where a second laser treatment, different than the first, is applied to the glass core substrate to sensitize a second portion of the glass core substrate at the first lateral location (i.e., where the application of operation 103 was applied) of the glass core substrate. The laser exposure or sensitization applies the same laser, such as an excimer laser at wavelength of 193 nm at shorter pulse width in the nano seconds regime, but with different characteristics that those applied at operation 103.

For example, the laser treatment of operation 103 and the laser treatment of operation 105 may differ in any suitable attributes to effect differing glass laser treated regions having different cross-sectional widths or dimensions and different depths. For example, the second laser treatment may sensitize the glass core substrate to form a sensitized pad region having a lower aspect ratio (i.e., height to width ratio) than that of the sensitized via region. It is noted that, alternatively, the laser treatment of operation 103 may form the sensitized pad region and the laser treatment of operation 105 may form the sensitized via region. For example, the first and second laser treatments may differ in any suitable manner inclusive of duration, intensity, scan rate, focal plane size, or a combination thereof. In some embodiments, the first laser treatment is at a first laser intensity and duration and the second laser treatment is at a second laser intensity and duration less than the first laser intensity and duration.

FIG. 7 illustrates a cross-sectional view of a glass core substrate workpiece 700 similar to glass core substrate workpiece 500 during and after the formation of pad laser treated regions 226, 229, in accordance with some embodiments. As shown, a second laser treatment 221 is applied to glass core substrate 201 at the lateral location of laser treated region 212 to form laser treated region 226. Second laser treatment 215 has a duration, intensity, scan rate, focal plane size, and so on to form laser treated region 226 to define an eventual pad portion of a metallization structure. After laser treatment 221, lateral shift 222 may provide alignment to laser treated region 213. After lateral shift 222, a second laser treatment 223 is applied to glass core substrate 201 to form laser treated region 229.

As with laser treated regions 212, 213, laser treated regions 226, 229 have characteristics relative to the bulk portions of glass core substrate 201 that make laser treated regions 226, 229 susceptible to subsequent etch processing. As shown, in some embodiments, one or both of laser treated regions 226, 229 have a lateral width, Wp. For example, lateral width Wp may be a diameter of laser treated regions 226, 229. As discussed, via and/or pad portions may have substantially circular cross-sectional shapes other shapes may be used. In particular, laser treated regions 226, 229 may have square or rectangular cross-sectional shapes. In some embodiments, laser treated regions 226, 229 may have square or rectangular cross-sectional shapes and laser treated regions 212 have circular cross-sectional shapes. However, other shapes and combinations may be deployed. In some embodiments, laser treated regions 226, 229 may be characterized as larger vias being shallower and having larger lateral widths with respect to laser treated regions 212, 213.

Lateral width Wp may be any suitable dimension such as a width in the range of 75 to 200 μm or more. In some embodiments, lateral width Wp is determined relative to lateral width Wv. For example, when lateral width Wv is 50 μm, lateral width Wp may be in the range of 75 to 100 μm; when lateral width Wv is 100 μm, lateral width Wp may be in the range of 150 to 200 μm; and so on. In some embodiments, lateral width Wp is not less than 25% greater than lateral width Wv (i.e., Wp≤1.25*Wv). In some embodiments, lateral width Wp is not less than 50% greater than lateral width Wv (i.e., Wp≤1.5*Wv). Other dimensions may be used.

Returning to FIG. 1, processing continues at operation 106, where the glass core substrate may optionally be moved to other lateral locations for additional laser treatments. For example, one or more other locations may be treated with additional laser exposures matching that applied at the first location or providing alternative laser exposures. After completion of all laser treatments, the glass core substrate to stage mounting is broken and the glass core substrate may be moved to other tooling for continued processing.

Processing continues at operation 107, where the sensitized laser treated portions or regions of the glass core substrate are removed via, for example, etch processing. The sensitized portions of the glass core substrate may be removed using any suitable technique or techniques. In some embodiments, the removal is performed by a hydrofluoric (HF) acid wet etch removal process that selectively removes the sensitized laser treated portions without removal (or substantial removal) of the untreated portions or regions of the glass core substrate.

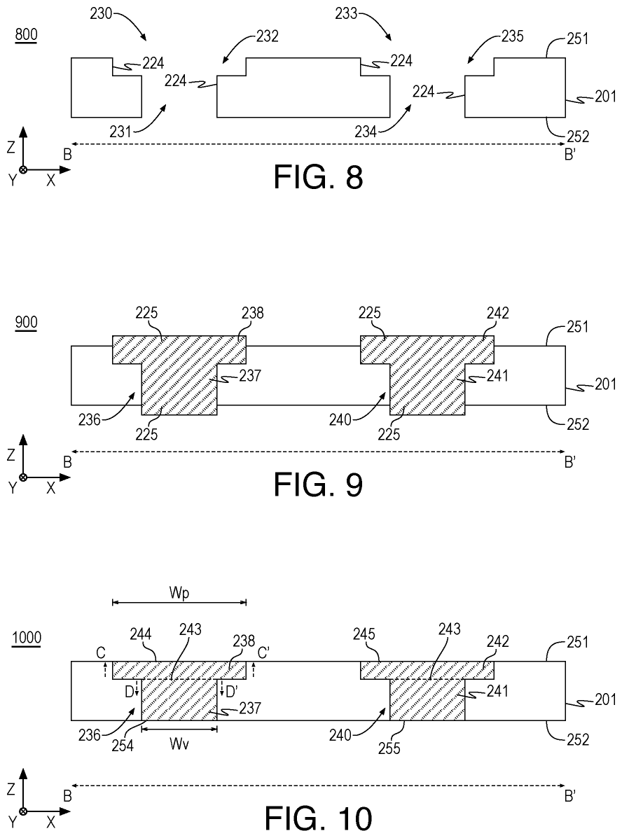

FIG. 8 illustrates a cross-sectional view of a glass core substrate workpiece 800 similar to glass core substrate workpiece 700 after the removal of laser treated regions 212, 213, 226, 229 to provide openings 230, 233 in glass core substrate 201, in accordance with some embodiments. As discussed, laser treated regions 212, 213, 226, 229 may be removed using any suitable technique or techniques such as HF acid etch processing. As shown, opening 230 includes a via opening 231 and a pad opening 232 corresponding to laser treated regions 212, 226. Similarly, opening 233 includes a via opening 234 and a pad opening 235 corresponding to laser treated regions 213, 229. Such openings 231, 232, 234, 235 may have any dimensions discussed herein with respect to laser treated regions 212, 213, 226, 229.

After such removal processing, sidewall surfaces 224 of openings 231, 232, 234, 235 have substantially smooth surfaces as opposed to other glass core substrate 201 material removal techniques such as mechanical drilling. Furthermore, such laser treatment/etch techniques form openings having few or no microcracks at sidewall surfaces 224.

Returning to FIG. 1, processing continues at operation 108, where the openings are filled with metallization material or materials. The openings may be filled with any suitable metal or conductive material such as copper. In some embodiments, the metallization of the openings includes depositing a seed layer via, for example, sputter processing followed by bulk metallization via electroplating techniques (e.g., electrolytic deposition, or elytic metallization) or electroless metal deposition techniques. For example, a seed copper layer may be deposited by sputter followed by elytic copper metallization.

FIG. 9 illustrates a cross-sectional view of a glass core substrate workpiece 900 similar to glass core substrate workpiece 800 after formation of metallization structures 236, 240 within openings 230, 233 of glass core substrate 201, in accordance with some embodiments. As shown, metallization structures 236, 240 fill openings 230, 233 (refer to FIG. 9). Metallization structures 236, 240 may also include overburden metal 225 formed over top surface 251 of glass core substrate 201.

Returning to FIG. 1, processing continues at operation 109, where any overburden metal may be removed using planarization techniques to form completed embedded metallization structure within glass core. Such planarization techniques may be performed using any suitable technique or techniques including chemical mechanical polishing operations.

FIG. 10 illustrates a cross-sectional view of a glass core substrate workpiece 1000 similar to glass core substrate workpiece 900 after removal of overburden metal 225 to provide completed embedded metallization structures 236, 240 in glass core substrate 201, in accordance with some embodiments. As discussed, metallization structures 236, 240 fill openings 230, 233 and, after removal of overburden metal 225, a top surface 244 of metallization structure 236 and a top surface 245 of metallization structure 240 are substantially coplanar with top surface 251 of glass core substrate 201. Similarly, after removal of overburden metal 225, a bottom surface 254 of metallization structure 236 and a bottom surface 255 of metallization structure 240 are substantially coplanar with bottom surface 252 of glass core substrate 201.

Thereby, an apparatus, glass core package, or glass core substrate workpiece 1000 is fabricated such that it includes glass core substrate 201 including top surface 251 and opposing bottom surface 252, and metallization structure 236 within opening 230 (refer to FIG. 8) of glass core substrate 201. In some embodiments, metallization structure 236 includes a via portion 237 and a pad portion 238. Similarly, metallization structure 240 is within opening 233 of glass core substrate 201, and metallization structure 240 includes a via portion 241 and a pad portion 242. Although labeled as via portions 237, 241 and pad portions 238, 242 for the sake of clarity, such portions may be labeled simply as portions, regions, or the like.

Via portions 237, 241 may have any lateral widths Wv and pad portions 238, 242 and may have any lateral widths Wp as discussed herein above. As shown, pad portions 238, 242 are continuous with via portions 237, 241. The term continuous indicates metallization structures 236, 240 are each an unbroken whole. Furthermore, metallization structures 236, 240 each a include continuous metal material. Also as shown, pad portions 238, 242 are on via portions 237, 241 at interfaces 243 between pad portions 238, 242. Notably, via portions 237, 241 and pad portions 238, 242 of metallization structures 236, 240 are continuous metals across interfaces. In some embodiments, via portions 237, 241 and pad portions 238, 242 each comprise copper, and the copper has a substantially matching microstructure across each of interfaces 143.

As discussed herein, pad portions 238, 242 have a greater lateral width Wp than a lateral width Wv of via portions 237, 241. In some embodiments, the lateral width Wp of pad portions 238, 242 is not less than 25% greater than the lateral width Wv of via portions 237, 241. In some embodiments, the lateral width Wp of pad portions 238, 242 is not less than 50% greater than the lateral width Wv of via portions 237, 241. Other dimensionalities may be used. As shown, in some embodiments, via portions 237, 241 extend through bottom surface of glass core substrate 201 (i.e., no glass material is exposed at bottom surfaces 254, 255 of via portions 237, 241). For example, via portions 237, 241 may be through glass vias. In some embodiments, via portions 237, 241 have a substantially cross-sectional shape.

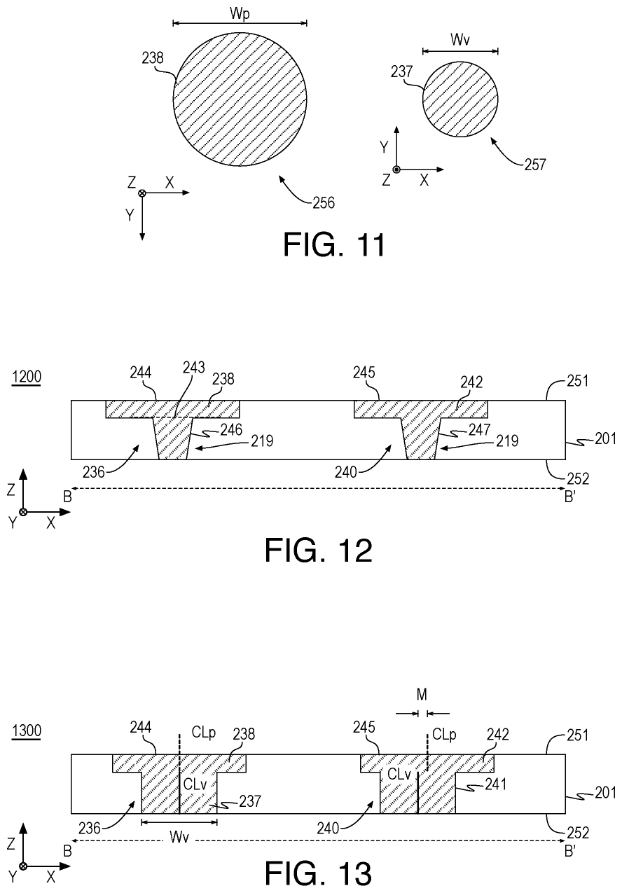

FIG. 11 illustrates cross-sectional views of pad portion 238 and via portion 237 taken at interface 243 of metallization structure 236, in accordance with some embodiments. For example, the cross-sectional view at the left of FIG. 11 is the view C-C′ in FIG. 10 and the cross-sectional view at the right of FIG. 11 is the view D-D′ in FIG. 10. As shown, in some embodiments, pad portion 238 of metallization structure 236 has a circular cross section 256 and/or via portion 237 of metallization structure 236 has a circular cross section 257. However, other cross-sectional shapes may be used. In some embodiments, pad portion 238 has a square or rectangular cross section, for example.

Furthermore FIG. 11 illustrates that via portion 237 has lateral width Wv at interface 243 and pad portion 238 has lateral width Wp at interface 243. As discussed, in some embodiments, lateral width Wp is not less than 25% greater than lateral width Wv. As used herein, the term at the interface indicates the plane or region of transition from lateral width Wv to lateral width Wp.

FIG. 12 illustrates a cross-sectional view of a glass core substrate workpiece 1200 similar to glass core substrate workpiece 600 after pad patterning, laser treated glass removal, metallization, and overburden metal removal to form metallization structures 236, 240 having tapered via portions 246, 247, in accordance with some embodiments. For example, processing may progress from glass core substrate workpiece 600 to glass core substrate workpiece 1200 as discussed with respect to FIGS. 7-10. As shown, in some embodiments, metallization structures 236, 240 have tapered via portions 246, 247 within tapered sidewalls 219. Tapered via portions 246, 247 may have any dimensions discussed herein with respect to FIG. 6. For example, to provide a TGV through a thickness Ts of glass core substrate 201, such tapering may occur.

The discussed techniques provide minimal or no overlap between via portions 237, 241 (or tapered via portions 246, 247) and pad portions 238, 242. In the illustrated examples, via portions 237, 241 (or tapered via portions 246, 247) are centered over pad portions 238, 242. However, such alignment is not necessarily deployed according to the layout or metallization design to be deployed.

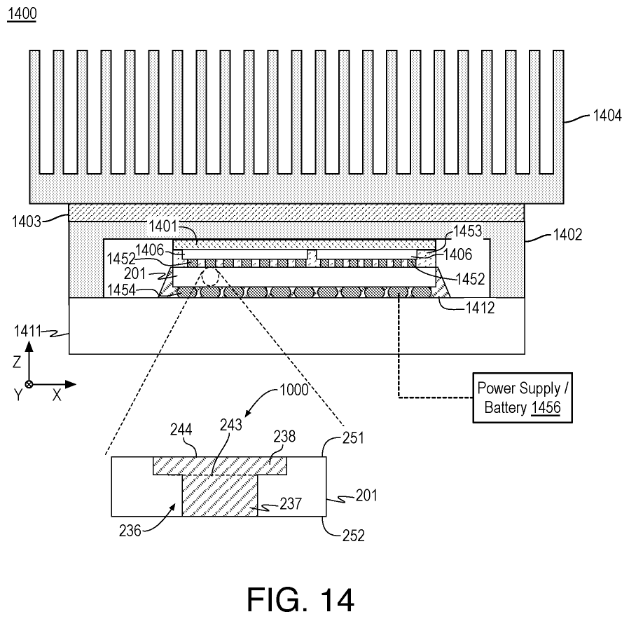

FIG. 13 illustrates a cross-sectional view of a glass core substrate workpiece 1300 similar to glass core substrate workpiece 1000 with a slight misalignment between via portion 241 and pad portion 242, in accordance with some embodiments. In the context of glass core substrate workpiece 1300, it is desirable that centerlines of via portions 237, 241 and pad portions 238, 242 are perfectly aligned (i.e., with zero misalignment). Herein, the term centerline indicates a line extending vertically through a center (e.g., centroid) of a volume having a length along the vertical dimension. The center or centroid may be taken at a center slice of the volume, for example.

As shown with respect to metallization structure 236, via portion 237 and pad portion 238 are perfectly aligned such that a centerline of pad portion 238 CLp (represented as a dashed line) and a centerline of via portion 237 CLv (represented as a solid line) are perfectly aligned, with no misalignment therebetween. In contrast, as shown with respect to metallization structure 240 an undesirable but tolerable misalignment between via portion 241 and pad portion 242 may result from the discussed processing. However, this misalignment is minimal and, though undesirable, enables miniaturization of the features of the glass core substrate workpieces discussed herein.

As shown, in some embodiments, a lateral misalignment M is between a centerline of pad portion 242 CLp (represented as a dashed line) and a centerline of via portion 237 CLv (represented as a solid line). Lateral misalignment M is in the x-y plane (and illustrated in the x-dimension of the x-y plane). In some embodiments, lateral misalignment M is not more than 500 nm. In some embodiments, lateral misalignment M is not more than 100 nm. In some embodiments, lateral misalignment M is not more than 5 nm.

Returning to FIG. 1, processing continues at operation 110, where any remaining package or assembly features may be competed, one or more integrated circuit dies may be attached to the glass core substrate, and the processed glass core substrate (i.e., with integrated circuit dies attached thereto) may be affixed to a system substrate. The resultant package may be output for incorporation into any suitable electronic device such as a laptop, a netbook, a notebook, an ultrabook, a smartphone, a tablet, a personal digital assistant PDA, an ultra-mobile PC, a mobile phone, a desktop computer, a server, a printer, a scanner, a monitor, a set-top box, an entertainment control unit, a digital camera, a portable music player, a digital video recorder, or the like.

FIG. 14 illustrates an example microelectronic device assembly 1400 including a glass core substrate having a metallization structure with different lateral widths, in accordance with some embodiments. Although illustrated with glass core substrate workpiece 1000, any glass core substrate workpiece discussed herein may be deployed in microelectronic device assembly 1400. As shown, microelectronic device assembly 1400 may include any number of integrated circuit dies 1406 mounted to glass core substrate 201 via die level interconnects 1452 and optionally embedded in a mold material 1453. However, any single IC die, 3D stacked multi-chip device, multi-chip composite structure, or the like may be deployed in microelectronic device assembly 1400. Glass core substrate 201 is coupled to a board 1411, such as a printed circuit board, via package level interconnects 1454 and partially encapsulated by underfill material 1412.

Microelectronic device assembly 1400 further includes a power supply 1456 coupled to one or more of board 1411, glass core substrate 201, integrated circuit dies 1406, or other components of microelectronic device assembly 1400. Power supply 1456 may include a battery, voltage converter, power supply circuitry, or the like. Microelectronic device assembly 1400 further includes a thermal interface material (TIM) 1401 disposed on top surfaces of integrated circuit dies 1406. TIM 1401 may include any suitable thermal interface material and may be characterized as TIM 1. Integrated heat spreader 1402 having a surface on TIM 1401 extends over integrated circuit dies 1406 and package substrate 1451, and is mounted to board 1411. Board 1411 may include any suitable substrate such as a motherboard, interposer, or the like. Microelectronic device assembly 1400 further includes TIM 1403 disposed on a top surface of integrated heat spreader 1402. TIM 1403 may include any suitable thermal interface material and may be characterized as TIM 2. TIM 1401 and TIM 1403 may be the same materials, or they may be different. Heat sink 1404 (e.g., an exemplary heat dissipation device or thermal solution) is on TIM 1403 and dissipates heat. Microelectronic device assembly 1400 may be used in desktop and server form factors. In other contexts, a heat solution such as a heat pipe or heat spreader may be mounted directly on TIM 1401. Such assemblies may be used in smaller form factor devices. Other heat dissipation devices may be used. Although illustrated with respect to integrated circuit dies 1406 being coupled to pad portion 244 (via die level interconnects 1452), in some embodiments, pad portion 244 may be coupled to board 1411 (via package level interconnects 1454).

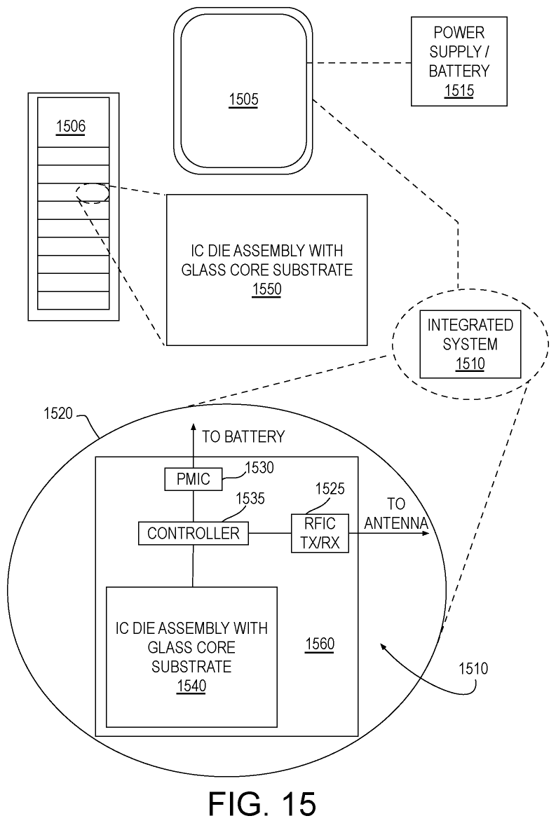

FIG. 15 illustrates exemplary systems deploying a glass core substrate having a metallization structure with different lateral widths, in accordance with some embodiments. The system may be a mobile computing platform 1505 and/or a data server machine 1506, for example. Either may employ a component assembly including a glass core substrate having a metallization structure with different lateral widths as described herein. Server machine 1506 may be any commercial server, for example, including any number of high-performance computing platforms disposed within a rack and networked together for electronic data processing, which in the exemplary embodiment includes an integrated circuit (IC) die assembly 1550 with a glass core substrate having a metallization structure with different lateral widths as described elsewhere herein. Mobile computing platform 1505 may be any portable device configured for each of electronic data display, electronic data processing, wireless electronic data transmission, or the like. For example, mobile computing platform 1505 may be any of a tablet, a smart phone, a laptop computer, etc., and may include a display screen (e.g., a capacitive, inductive, resistive, or optical touchscreen), a chip-level or package-level integrated system 1510, and a battery 1515. Although illustrated with respect to mobile computing platform 1505, in other examples, chip-level or package-level integrated system 1510 and a battery 1515 may be implemented in a desktop computing platform, an automotive computing platform, an internet of things platform, or the like. In some examples, the disclosed systems may include a sub-system 1560 such as a system on a chip (SOC) or an integrated system of multiple ICs, which is illustrated with respect to mobile computing platform 1505.

Whether disposed within integrated system 1510 illustrated in expanded view 1520 or as a stand-alone packaged device within data server machine 1506, sub-system 1560 may include memory circuitry and/or processor circuitry 1540 (e.g., RAM, a microprocessor, a multi-core microprocessor, graphics processor, etc.), a power management integrated circuit (PMIC) 1530, a controller 1535, and a radio frequency integrated circuit (RFIC) 1525 (e.g., including a wideband RF transmitter and/or receiver (TX/RX)). As shown, one or more IC dice, such as memory circuitry and/or processor circuitry 1540 may be packaged, assembled and implemented, such that the package has a glass core substrate having a metallization structure with different lateral widths as described herein. In some embodiments, RFIC 1525 includes a digital baseband and an analog front end module further comprising a power amplifier on a transmit path and a low noise amplifier on a receive path). Functionally, PMIC 1530 may perform battery power regulation, DC-to-DC conversion, etc., and so has an input coupled to battery 1515, and an output providing a current supply to other functional modules. As further illustrated in FIG. 15, in the exemplary embodiment, RFIC 1525 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 1540 may provide memory functionality for sub-system 1560, high level control, data processing and the like for sub-system 1560. In alternative implementations, each of the SOC modules may be integrated onto separate ICs coupled to a package substrate, interposer, or board.

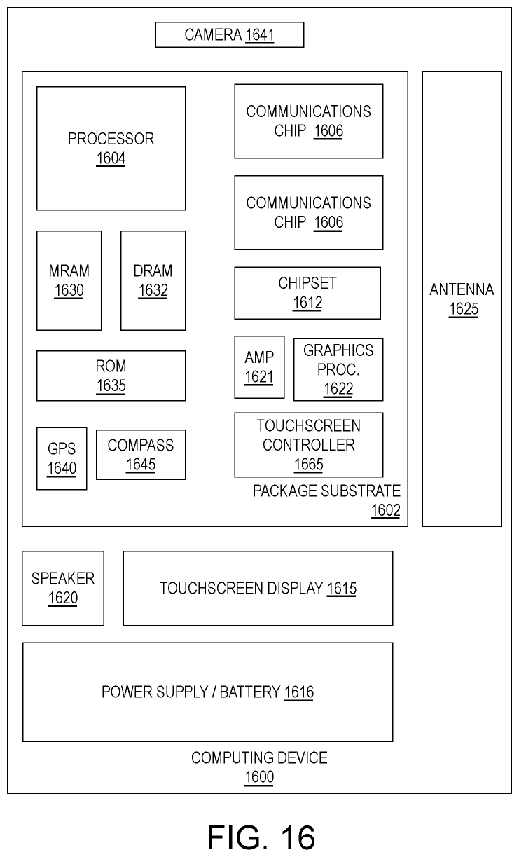

FIG. 16 is a functional block diagram of an electronic computing device 1600, in accordance with some embodiments. For example, device 1600 may, via any suitable component therein, employ a glass core substrate having a metallization structure with different lateral widths in accordance with any embodiments described elsewhere herein. Device 1600 further includes a motherboard or package substrate 1602 hosting a number of components, such as, but not limited to, a processor 1604 (e.g., an applications processor). Processor 1604 may be physically and/or electrically coupled to package substrate 1602. In some examples, processor 1604 is within a packaged IC assembly that includes a glass core substrate having a metallization structure with different lateral widths as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1606 may also be physically and/or electrically coupled to the package substrate 1602. In further implementations, communication chips 1606 may be part of processor 1604. Depending on its applications, computing device 1600 may include other components that may or may not be physically and electrically coupled to package substrate 1602. These other components include, but are not limited to, volatile memory (e.g., DRAM 1632), non-volatile memory (e.g., ROM 1635), flash memory (e.g., NAND or NOR), magnetic memory (MRAM 1630), a graphics processor 1622, a digital signal processor, a crypto processor, a chipset 1612, an antenna 1625, touchscreen display 1615, touchscreen controller 1665, battery 1616, audio codec, video codec, power amplifier 1621, global positioning system (GPS) device 1640, compass 1645, accelerometer, gyroscope, speaker 1620, camera 1641, and mass storage device (such as hard disk drive, solid-state drive (SSD), compact disk (CD), digital versatile disk (DVD), and so forth, or the like.

Communication chips 1606 may enable wireless communications for the transfer of data to and from the computing device 1600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1606 may implement any of a number of wireless standards or protocols, including, but not limited to, those described elsewhere herein. As discussed, computing device 1600 may include a plurality of communication chips 1606. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a glass core substrate comprising a first surface and an opposing second surface, and a metallization structure within an opening of the glass core substrate, the metallization structure comprising a first portion, and a second portion continuous with the first portion, the second portion on the first portion at an interface between the first and second portions, the first portion having a first lateral width at the interface and the second portion having a second lateral width at the interface, wherein the second lateral width is not less than 25% greater than the first lateral width, and wherein the second portion comprises a top surface substantially coplanar with the second surface of the glass core substrate.

In one or more second embodiments, further to the first embodiments, the second lateral width is not less than 50% greater than the first lateral width.

In one or more third embodiments, further to the first or second embodiments, the first portion has a first centerline extending vertically through a length of the first portion and the second portion has a second centerline extending vertically through a length of the second portion, wherein the first and second centerlines are laterally misaligned by not more than 100 nm.

In one or more fourth embodiments, further to the first through third embodiments, the first and second centerlines are laterally misaligned by not more than 5 nm.

In one or more fifth embodiments, further to the first through fourth embodiments, the first portion extends through the first surface of the glass core substrate.

In one or more sixth embodiments, further to the first through fifth embodiments, the first portion comprises a through glass via having a substantially circular cross sectional shape, and the second portion comprises a pad.

In one or more seventh embodiments, further to the first through sixth embodiments, the first portion comprises a taper to a third lateral width of the first portion at the first surface of the glass core substrate, wherein the third lateral width is less than the first lateral width.

In one or more eighth embodiments, further to the first through seventh embodiments, the first and second portions of the metallization structure each comprise copper, the copper having a substantially matching microstructure across the interface.

In one or more ninth embodiments, further to the first through eighth embodiments, the glass core substrate comprises sodium borosilicate glass.

In one or more tenth embodiments, a system comprises an apparatus according to any of the apparatuses of the first through ninth embodiments, and one or both of an integrated circuit die and a printed circuit board coupled to the glass core substrates.

In one or more eleventh embodiments, a system comprises a glass core substrate comprising a first surface and an opposing second surface, a continuous metallization structure within the glass core substrate, the continuous metallization structure comprising a via extending through the first surface and a pad extending through the second surface, the pad on the via at an interface therebetween, wherein the pad has a first lateral width at the interface that is not less than 25% greater than a second lateral width of the via at the interface, and wherein the pad comprises a top surface substantially coplanar with the second surface of the glass core substrate, and one of an integrated circuit die or a printed circuit board coupled to the pad.

In one or more twelfth embodiments, further to the eleventh embodiments, the first lateral width is not less than 50% greater than the second lateral width, and wherein the pad has a first centerline and the via has a second centerline laterally misaligned by not more than 50 nm.

In one or more thirteenth embodiments, further to the eleventh or twelfth embodiments, the via comprises a taper to a third lateral width at the first surface, wherein the third lateral width is less than the first lateral width.

In one or more fourteenth embodiments, further to the eleventh through thirteenth embodiments, the first and second portions of the metallization structure each comprise copper, the copper having a substantially matching microstructure across the interface.

In one or more fifteenth embodiments, further to the eleventh through fourteenth embodiments, the integrated circuit die is coupled to the pad, the system further comprising the printed circuit board coupled to the first surface of the glass core substrate.

In one or more sixteenth embodiments, a method comprises mounting a glass core substrate to a stage to provide a glass core substrate to stage mounting, applying, during said glass core substrate to stage mounting, a first laser treatment to the glass core substrate to sensitize a first portion of the glass core substrate, the first portion having a first lateral dimension, applying, during said glass core substrate to stage mounting, a second laser treatment to the glass core substrate to sensitize a second portion of the glass core substrate continuous with the first portion, the second portion having a second lateral dimension less than the first lateral dimension, and removing the sensitized first and second portions via an etch process.

In one or more seventeenth embodiments, further to the sixteenth embodiments, the first and second laser treatments are applied at a first lateral location of the glass core substrate without intervening movement to a second lateral location of the glass core substrate.

In one or more eighteenth embodiments, further to the sixteenth or seventeenth embodiments, the first and second laser treatments are applied at a first lateral location of the glass core substrate, and the method further comprises moving the stage, applying the first laser treatment to a second lateral location of the glass core substrate, and returning to the first lateral location prior to the application of the second laser treatment.

In one or more nineteenth embodiments, further to the sixteenth through eighteenth embodiments, said second laser treatment is performed prior to said first laser treatment.

In one or more twentieth embodiments, further to the sixteenth through nineteenth embodiments, the first laser treatment is at a first laser intensity and duration and the second laser treatment is at a second laser intensity and duration less than the first laser intensity and duration.

In one or more twenty-first embodiments, further to the sixteenth through twentieth embodiments, the method further comprises forming a metallization structure in an opening vacated by the first and second portions, the metallization structure comprising a via portion extending through a bottom surface of the glass core substrate and a pad portion extending through a top surface of the glass core substrate, the pad portion having a first lateral width that is not less than 25% greater than a second lateral width of the via portion.

In one or more twenty-second embodiments, further to the sixteenth through twenty-first embodiments, the glass core substrate comprises sodium borosilicate glass, the first and second laser treatments comprise application of an excimer laser at a wavelength of about 193 nm, and the etch process comprises a hydrofluoric acid etch.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a glass core substrate comprising a first surface and an opposing second surface; and
a metallization structure within an opening of the glass core substrate, the metallization structure comprising:
a first portion; and
a second portion continuous with the first portion, the second portion on the first portion at an interface between the first and second portions, the first portion having a first lateral width at the interface and the second portion having a second lateral width at the interface, wherein the second lateral width is not less than 25% greater than the first lateral width, and wherein the second portion comprises a top surface substantially coplanar with the second surface of the glass core substrate.

2. The apparatus of claim 1, wherein the second lateral width is not less than 50% greater than the first lateral width.

3. The apparatus of claim 1, wherein the first portion has a first centerline extending vertically through a length of the first portion and the second portion has a second centerline extending vertically through a length of the second portion, wherein the first and second centerlines are laterally misaligned by not more than 100 nm.

4. The apparatus of claim 3, wherein the first and second centerlines are laterally misaligned by not more than 5 nm.

5. The apparatus of claim 1, wherein the first portion extends through the first surface of the glass core substrate.

6. The apparatus of claim 5, wherein the first portion comprises a through glass via having a substantially circular cross sectional shape, and the second portion comprises a pad.

7. The apparatus of claim 6, wherein the first portion comprises a taper to a third lateral width of the first portion at the first surface of the glass core substrate, wherein the third lateral width is less than the first lateral width.

8. The apparatus of claim 1, wherein the first and second portions of the metallization structure each comprise copper, the copper having a substantially matching microstructure across the interface.

9. The apparatus of claim 1, wherein the glass core substrate comprises sodium borosilicate glass.

10. A system, comprising:
a glass core substrate comprising a first surface and an opposing second surface;
a continuous metallization structure within the glass core substrate, the continuous metallization structure comprising a via extending through the first surface and a pad extending through the second surface, the pad on the via at an interface therebetween, wherein the pad has a first lateral width at the interface that is not less than 25% greater than a second lateral width of the via at the interface, and wherein the pad comprises a top surface substantially coplanar with the second surface of the glass core substrate; and
one of an integrated circuit die or a printed circuit board coupled to the pad.

11. The system of claim 10, wherein the first lateral width is not less than 50% greater than the second lateral width, and wherein the pad has a first centerline and the via has a second centerline laterally misaligned by not more than 50 nm.

12. The system of claim 10, wherein the via comprises a taper to a third lateral width at the first surface, wherein the third lateral width is less than the first lateral width.

13. The system of claim 10, wherein the first and second portions of the metallization structure each comprise copper, the copper having a substantially matching microstructure across the interface.

14. The system of claim 10, wherein the integrated circuit die is coupled to the pad, the system further comprising the printed circuit board coupled to the first surface of the glass core substrate.

15. A method, comprising:
mounting a glass core substrate to a stage to provide a glass core substrate to stage mounting;
applying, during said glass core substrate to stage mounting, a first laser treatment to the glass core substrate to sensitize a first portion of the glass core substrate, the first portion having a first lateral dimension;
applying, during said glass core substrate to stage mounting, a second laser treatment to the glass core substrate to sensitize a second portion of the glass core substrate continuous with the first portion, the second portion having a second lateral dimension less than the first lateral dimension; and
removing the sensitized first and second portions via an etch process.

16. The method of claim 15, wherein the first and second laser treatments are applied at a first lateral location of the glass core substrate without intervening movement to a second lateral location of the glass core substrate.

17. The method of claim 15, wherein the first and second laser treatments are applied at a first lateral location of the glass core substrate, the method further comprising:
moving the stage;
applying the first laser treatment to a second lateral location of the glass core substrate; and
returning to the first lateral location prior to the application of the second laser treatment.

18. The method of claim 15, wherein said second laser treatment is performed prior to said first laser treatment.

19. The method of claim 15, wherein the first laser treatment is at a first laser intensity and duration and the second laser treatment is at a second laser intensity and duration less than the first laser intensity and duration.

20. The method of claim 15, further comprising:
forming a metallization structure in an opening vacated by the first and second portions, the metallization structure comprising a via portion extending through a bottom surface of the glass core substrate and a pad portion extending through a top surface of the glass core substrate, the pad portion having a first lateral width that is not less than 25% greater than a second lateral width of the via portion.
